(19) United States
(12) Patent Application Publication
(10) Pub. No.: US 2015/0270148 A1
(43) Pub. Date: Sep. 24, 2015

(54) ETCHING APPARATUS

(71) Applicant: Hitachi High-Technologies Corporation, Tokyo (JP)

(72) Inventors: Kazunori Shinoda, Tokyo (JP); Tsutomu Tetsuka, Tokyo (JP); Kenji Maeda, Tokyo (JP)

(73) Assignee: HITACHI HIGH-TECHNOLOGIES CORPORATION

(21) Appl. No.: 14/627,002

(22) Filed: Feb. 20, 2015

(30) Foreign Application Priority Data
Mar. 20, 2014 (JP) 2014-058745

(51) Int. Cl. H01L 21/67; H01L 21/02; H01L 21/268; H01J 37/32

(52) U.S. Cl. CPC H01L 21/67069; H01J 37/32009; H01J 37/32724; H01L 21/02057; H01L 21/268

(57) ABSTRACT

An etching apparatus including a processing chamber, a supply unit for reactive species, and a lamp for vacuum-ultraviolet light irradiation is prepared. In the etching apparatus, etching can be performed by repeating a first step of adsorbing the reactive species to a surface of a wafer to form byproducts, a second step of irradiating the surface of the wafer with vacuum-ultraviolet light from the lamp for vacuum-ultraviolet light irradiation, to desorb the byproducts, and a third step of exhausting the desorbed byproducts.

### BACKGROUND OF THE INVENTION

The present invention relates to an etching apparatus, and more particularly, to a technique that is effectively applied to an etching apparatus that performs etching processing for a sample using an adsorption/desorption system.

Miniaturization and higher performance of an electronic apparatus have progressed by microfabrication and higher integration of a semiconductor device constituting the electronic apparatus. In recent years, a higher aspect ratio of a device structure has been rapidly progressing with the progress of the refinement and the higher integration of the semiconductor device.

If a fine pattern having a high aspect ratio is created, the pattern is liable to collapse due to surface tension during drying of a rinse liquid in a wet cleaning process and a wet removal process using a chemical liquid. It has been known that if a pattern having a high aspect ratio of silicon (Si), for example, is used, a limit value of a pattern interval at which the pattern starts to collapse when the pattern interval is narrowed increases in proportion to the square of the aspect ratio Therefore, it is predicted that as the refinement and the higher aspect ratio progress, the collapse of the pattern in a wet cleaning/removal process becomes a great issue in the future.

On the other hand, an etching apparatus using an adsorption/desorption system using gas, a radical, or the like has been put to practical use as a cleaning/removal technique using no chemical liquid in recent years. In the adsorption/desorption system, an etchant such as gas, a radical, or a vapor is supplied to a processing chamber on which a wafer is mounted and is adsorbed to a surface of a film to be removed, and the wafer is then heated, to desorb byproducts produced by reaction of the etchant and a film to be removed. Adsorption and desorption processes are repeated as one cycle a required number of times, to etch away a target film.

In this method, the chemical liquid is not used. Thus, a pattern can be prevented from collapsing in a removal process. An etching amount in one cycle of adsorption and desorption is small and constant, and is controlled the number of times of repetition of the cycle. Thus, controllability of the etching amount is high. Ion impact is not used, unlike in reactive ion etching serving as a general-purpose etching method. This is advantageous in that selectivity of an undercoating material is high, for example.

For an etching apparatus using an adsorption/desorption system, US. Patent Publication No. 2004/0185670A1 describes an apparatus that includes a chamber for chemical treatment and a chamber for heat treatment and etches away a silicon dioxide (SiO₂) film on a wafer using hydrogen fluoride (HF) gas and ammonia (NH₃) gas. US. Patent Publication No 2008/0268645A1 describes an etching apparatus in which a wafer stage for reactive species adsorption and a heating shower plate for desorption processing are provided within one chamber. JP-A-2003-347278 describes an etching apparatus in which a wafer stage for etchant adsorption and a halogen lamp for heating are provided in one chamber.

### SUMMARY OF THE INVENTION

However, in an etching apparatus using heating to desorb byproducts, throughput in wafer processing is low The etching apparatus increases in size by providing a chamber dedicated to heating or a contaminating material is generated because there is a mechanical drive portion within a processing chamber.

The present invention is directed to providing an etching apparatus capable of enhancing throughput in wafer processing in an etching process.

The foregoing object and new features of the present invention will become apparent from the following description of the specification and the attached drawings

The outline of a typical one of embodiments disclosed in the present application will be briefly described as follows

An etching apparatus according to an embodiment includes a processing chamber, a supply unit for reactive species, and a lamp for vacuum-ultraviolet light irradiation, and performs etching by repeating a first step of adsorbing the reactive species to a surface of a wafer to form byproducts, a second step of irradiating the surface of the wafer with vacuum-ultraviolet light using a lamp for vacuum-ultraviolet light irradiation, to desorb the byproducts, and a third step of exhausting the desorbed byproducts.

An effect obtained by typical one of inventions disclosed in the present application will be briefly described as follows.

According to the present invention, the performance of the etching apparatus can be improved. Particularly, higher throughput of the etching apparatus can be achieved.

Other objects, features, and advantages of the invention will become apparent from the following description of the embodiments of the invention taken in conjunction with the accompanying drawings.

### BRIEF DESCRIPTION OF THE DRAWINGS

FIG. 1 is a schematic view of an etching apparatus according to a first embodiment of the present invention;

FIG. 2 is a schematic view of an etching apparatus according to a second embodiment of the present invention;

FIG. 3 is a schematic view of an etching apparatus in a first comparative example;

FIG. 4 is a schematic view of an etching apparatus in a second comparative example; and

FIG. 5 is a schematic view of an etching apparatus in a third comparative example.

### DETAILED DESCRIPTION OF THE EMBODIMENT

Embodiments of the present invention will be described in detail below with reference to the drawings. Members having identical functions are assigned identical reference numerals in all the drawings for illustrating the embodiments, and repeated description thereof is omitted. In the following embodiments, description of identical or similar portions is not repeated in principle, except if it is particularly necessary.

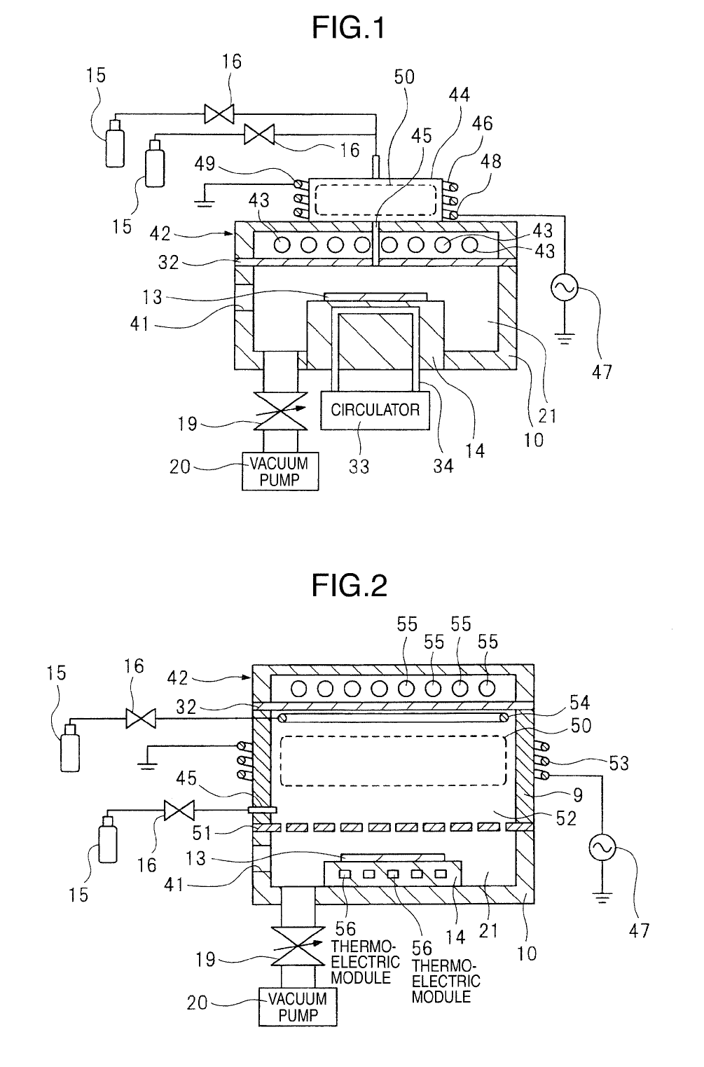

The present embodiment is directed to performing etching using ultraviolet light in an etching apparatus that etches away a silicon oxynitride (SiON) film on a silicon (Si) wafer using a radical including nitrogen trifluoride (NF₃) gas and ammonia (NH₃) gas, to improve the performance of the etching apparatus The present embodiment will be described below with reference to FIG. 1. FIG. 1 is a schematic view illustrating a configuration of the etching apparatus according to the present embodiment.

As illustrated in FIG. 1, the etching apparatus according to the present embodiment includes a vessel 10 constituting a vacuum chamber. The inside of the vessel 10 is a processing chamber 21. A wafer stage 14 is provided within the processing chamber 21, and a lamp unit 42 is provided directly on the processing chamber 21 with a silica glass plate 32 sandwiched therebetween. A plurality of lamps for vacuum-ultraviolet light irradiation 43 is arranged within the lamp unit 42. A radical source 44 is provided directly on the lamp unit 42. The processing chamber 21, the silica glass plate 32, and the lamp unit 42 are adapted to have an airtight structure using vacuum seal means such as an O-ring.

Gas or dust within the processing chamber 21 is exhausted using a vacuum pump 20 connected to the vessel 10 via a variable conductance valve 19. A gas supply unit including a plurality of gas cylinders 15 and a plurality of valves 16 is connected to the processing chamber 21 via the radical source 44. The gas supplied from each of the gas cylinders 15 is introduced into the radical source 44 via the valve 16. The gas introduced into the radical source 44 is activated within the radical source 44 to generate a radical. The generated radical is supplied to the processing chamber 21 via a gas introduction pipe 45. The radical source 44 includes a coiled antenna 46 arranged to wrap around the outer periphery of a vessel constituting the radical source 44. An output of a high frequency power source 47 is connected to a feeding point 48 serving as one end of the coiled antenna 46, and a ground point 49 serving as the other end thereof is grounded.

A cooling device including a circulator 33 and a cooling line 34 cools the wafer stage 14. The circulator 33 is installed outside the vessel 10. The cooling line 34 connected to the circulator 33 is laid within the wafer stage 14. The vessel 10 has a wafer conveyance port 41, which is used to carry the wafer 13 serving as a member to be processed into the processing chamber 21 and can be opened and closed, on its sidewall.

A material for the vessel 10 constituting an inner wall of the processing chamber 21 is desirably one having excellent plasma resistance and hardly generating heavy-metal contamination and contamination with a contaminating material in the wafer 13 to be mounted on the wafer stage 14. The material for the vessel 10 desirably includes aluminum (Al) whose inner surface has been alumited. Alternatively, the vessel 10 may be a vessel, made of an aluminum base material, having a material such as yttria (Y₂O₃), alumina (Al₂O₃), or silicon oxide (SiO₂) thermally sprayed onto its inner surface. The variable conductance valve 19 and the vacuum pump 20, which are connected to the processing chamber 21, can keep pressure within the processing chamber 21 constant with a desired flow of process gas caused to flow from the gas cylinder 15 or the like.

A material for the wafer stage 14 is desirably aluminum whose surface is alumited or a titanium (Ti) alloy. The circulator 33 and the cooling line 34 can control the temperature of the wafer stage 14 to 20° C. even when the etching apparatus is operated. Further, the wafer stage 14 includes a lift pin (not illustrated) for raising and lowering the wafer.

The silica glass plate 32 is installed on the processing chamber 21 so that an airtight state of the processing chamber 21 is maintained using the vacuum seal means such as the O-ring. That is, the top of the processing chamber 21, excluding its part provided with the gas introduction pipe 45, is covered with the silica glass plate 32. A material having high transmissivity of vacuum-ultraviolet light is desirably used for the silica glass plate 32. A raw material having a significantly high purity, e.g., ultrapure fused silica glass formed by being fused with an oxyhydrogen flame or silica glass obtained by hydrolyzing silicon tetrachloride (SiCl₄) using a Bernoulli's method.

While an example using the fused silica glass for a window between the processing chamber 21 and the lamp for vacuum-ultraviolet light irradiation 43 will be described in the present embodiment, a material for the window is not limited to the fused silica glass if it is superior in transmissivity of vacuum-ultraviolet light. For example, a fluoride material such as calcium fluoride (CaF₂) or magnesium fluoride (MgF₂) may be used. The gas introduction pipe 45 serving as a rectification unit penetrates the center of the silica glass plate 32 so that the gas, which has been activated within the radical source 44, can be supplied to the processing chamber 21.

A shape of the rectification unit is selected, as needed, for the purpose of changing a supply form of the radical to the processing chamber 21. If a disk-shaped shower plate or a doughnut-shaped introduction pipe, for example, is used, the radical can be uniformly introduced into the vacuum chamber. In the case, a material for the rectification unit is desirably a material having high plasma resistance, hardly turning into a contaminating material, and hardly contaminating the inside of the processing chamber, i.e., fused silica or a yttria sintered body

The lamp unit 42 having the plurality of lamps for vacuum-ultraviolet light irradiation 43 in its inner part is provided on the top of the silica glass plate 32. As the lamp for vacuum-ultraviolet light irradiation 43 can include a lamp using a dielectric barrier discharge of rare gas as an excitation source. The lamp for vacuum-ultraviolet light irradiation 43 is a lamp for irradiating vacuum-ultraviolet light having a center wavelength of 172 nm using a xenon (Xe₂) discharge as an excitation source. The power density of the lamp for vacuum-ultraviolet light irradiation 43 is 20 mW/cm².

A method for adsorbing an etchant such as a radical to a surface of a film to be removed and removing byproducts produced by reaction of the etchant and the film to be removed can include heating using a halogen lamp or the like, as described below, On the other hand, if the above-mentioned vacuum-ultraviolet light to be irradiated from the lamp for vacuum-ultraviolet light irradiation 43 is used, light energy having a magnitude of not less than that of bond energy which is required to decompose byproducts can be applied to the byproducts. Thus, a bond of the byproducts is broken so that the byproducts can be efficiently desorbed.

The wavelength of the vacuum-ultraviolet light to be irradiated from the lamp for vacuum-ultraviolet light irradiation 43 to desorb the byproducts is from 10 nm to 200 nm. However, an effect of desorbing the byproducts can also be obtained, like in near-ultraviolet light having a wavelength in a range of 200 nm to 380 nm. The power density of the lamp for vacuum-ultraviolet light irradiation 43 in the present embodiment is as low as 20 mW/cm². Thus, a rise in temperature of the wafer 13 by light irradiation from the lamp for vacuum-ultraviolet light irradiation 43 is small, and the temperature of the wafer 13, which has been cooled by the cooling line 34, is maintained at 20° C.

The lamp for vacuum ultraviolet light irradiation 43 in the present embodiment irradiates the vacuum-ultraviolet light having a center wavelength of 172 nm by the Xe₂ discharge. On the other hand, a lamp for irradiating near-ultraviolet light having a center wavelength of 222 nm by a krypton chloride (KrCl) discharge, a lamp for irradiating near-ultraviolet light having a center wavelength of 308 nm by a xenon chloride (XeCl) discharge, or the like may be used. That is, light to be irradiated to desorb the byproducts may be not only the vacuum-ultraviolet light but also the near-ultraviolet light.

The frequency of the high frequency power source 47 connected to the radical source 44 is selected, as needed, between 400 kHz to 40 MHz. The frequency of the high frequency power source 47 in the present embodiment is 13.56 MHz. The high frequency power source 47 has a frequency matching function. That is, the high frequency power source 47 has a function enabling an output frequency to be changed in a range of ±5% to ±10% with respect to a center frequency of 13.56 MHz and enabling feedback control of the frequency so that a ratio Pᵣ/P_{f} of traveling-wave power P_{f} to be monitored by an output portion of the high frequency power source 47 to reflection wave power Pᵣ decreases.

The type of the gas to be supplied from the plurality of gas cylinders 15 to the radical source 44 is selected, as needed, depending on a film to be etched. If the SiO₂ film or the SiON film, for example, is removed by etching processing, a combination of gas containing hydrogen (H) and gas containing fluorine (F) is used. Examples of the gas containing hydrogen include anhydrous hydrogen fluoride (HF), hydrogen (H₂), ammonia (NH₃), methane (CH₄), fluoromethane (CH₃F), and difluoromethane (CH₂F₂). Examples of the gas containing fluorine include nitrogen trifluoride (NF₃), carbon tetrafluoride (CF₄), sulfur hexafluoride (SF₆), trifluoromethane (CHF₃), difluoromethane (CH₂F₂), fluoromethane (CH₃F), and anhydrous hydrogen fluoride (HF).

The gas containing hydrogen or the gas containing fluorine can also be diluted, as needed, by adding inert gas such as argon (Ar), helium (He), or nitrogen (N₂) thereto.

If a silicon nitride (SiN) film is removed by etching processing, a mixed gas containing nitrogen (N), oxygen (O), and fluorine (F) is used in addition to a combination of the gas containing hydrogen and the gas containing fluorine, as described above. Examples of the gas containing nitrogen include nitrogen (N₂), nitric oxide (NO), nitrous oxide (N₂O), nitrogen dioxide (NO₂), and dinitrogen pentaoxide (N₂O₅). Examples of the gas containing oxygen include oxygen (O₂), carbon dioxide (CO₂), water (H₂O), nitric oxide (NO), and nitrous oxide (N₂O).

The etching apparatus according to the present embodiment includes the processing chamber 21, the wafer stage 14, the glass cylinders 15, the valves 16, the variable conductance valve 19, the vacuum pump 20, the silica glass plate 32, the circulator 33, the cooling line 34, the lamp unit 42, the lamp for vacuum-ultraviolet light irradiation 43, the radical source 44, the gas introduction pipe 45, the coiled antenna 46, and the high frequency power source 47, as described above.

The etching of the SiON film in the present embodiment progresses by repeatedly performing three steps, described below. That is, the etching progresses by repeatedly performing a first step of supplying a radical containing hydrogen and fluorine to the Si wafer having the SiON film formed therein and adsorbing the radical to the SiON film, to cause a chemical reaction therebetween, a second step of irradiating the Si wafer with vacuum-ultraviolet light or near-ultraviolet light to desorb byproducts produced by the chemical reaction, and a third step of exhausting the desorbed byproducts.

A specific procedure for an etching process using the etching apparatus according to the present embodiment will be described below. First, the wafer 13 from which the SiON film is to be removed is carried into the etching apparatus via the wafer conveyance port 41 by a wafer conveyance device (not illustrated), and is mounted on the wafer stage 14. At this time, the temperature of the wafer stage 14 is controlled to 20° C. by the circulator 33 and the cooling line 34, and the temperature of the wafer 13 is maintained at 20° C. after that. The wafer 13 is composed of monocrystalline silicon (Si), for example.

Then, the processing chamber 21 is evacuated via the variable conductance valve 19 using the vacuum pump 20 while the wafer conveyance port 41 is closed so that the processing chamber 21 is kept airtight. On the other hand, when the NF₃ gas and the NH₃ gas are supplied from each of the gas cylinders 15 to the radical source 44 while high frequency power from the high frequency power source 47 is supplied to the coiled antenna 46, a plasma 50 is formed within the radical source 44. That is, when a current is caused to flow through the coiled antenna 46, the plasma 50 is generated within the radical source 44. At this time, the flow rate of the NF₃ gas is 10 sccm, and the flow rate of the NH₃ gas is 50 sccm. In FIG. 1, the plasma 50 is generated at a position enclosed by a broken line.

Processing gas containing NF₃ and NH₃ is activated by the plasma 50, to be an etchant including a radical, and flows into the processing chamber 21 via the gas introduction pipe 45. The etchant including the radical, which has flowed into the processing chamber 21, is uniformly dispersed to the entire processing chamber 21, and is adsorbed to the entire upper surface of the wafer 13 mounted on the wafer stage 14. The etchant, which has been adsorbed to the wafer 13, reacts with the SiON film exposed to the surface of the wafer 13, to form byproducts including a mixture of Si, N, H, F, and O. A composition of the byproducts is (NH₄)₂SiF₆, for example.

After a lapse of a processing time set to form the byproducts by performing the above-mentioned process, the supply of the processing gas by the valve 16 is stopped while the radical source 44 is also stopped. The gas remaining in the processing chamber 21 is exhausted via the variable conductance valve 19 using the vacuum pump 20.

Then, the lamp for vacuum-ultraviolet light irradiation 43 is turned on, and the upper surface of the wafer 13 is irradiated with vacuum-ultraviolet light having a center wavelength of 172 nm. The power density of the irradiated light is 20 mW/cm², and an irradiation time is one minute. The vacuum-ultraviolet light having a center wavelength of 172 nm has photon energy that is as high as 697.5 kJ/mol. Thus, a bond and a back bond of (NH₄)₂SiF₆ constituting the byproducts are broken, and the byproducts are desorbed from the surface of the wafer in the form of NH₃, HF, or silicon tetrafluoride (SiF₄). As a result, a part or the whole of the SiON film is removed from the surface of the wafer 13 serving as the member to be processed.

During the reaction, the wafer 13 is cooled using the circulator 33 and the cooling line 34, and the temperature thereof is maintained at 20° C. The power density of the irradiated light from the lamp for vacuum-ultraviolet light irradiation 43 is as low as 20 mW/cm². Thus, the temperature of the wafer 13 does not rise, and is maintained at 20° C. throughout the above-mentioned processes due to an effect of the circulator 33 and the cooling line 34.

After a lapse of a processing time set to desorb the byproducts on the surface of the wafer 13, the lamp for vacuum-ultraviolet light irradiation 43 goes out, and the gas remaining in the processing chamber 21 is exhausted using the vacuum pump 20.

As described above, the etching process performed by the etching apparatus according to the present embodiment includes an adsorption process for adsorbing the etchant including the radical to the wafer 13 to form the byproducts, and a desorption process for desorbing the byproducts by irradiating the vacuum-ultraviolet light. A part of the SiON film is etched away through the adsorption process and the desorption process. Atypical etching amount in one cycle of the adsorption and the desorption is 1 nm, and a period of time required for the one cycle is two minutes. That is, the upper surface of the SiON film retreats by an amount of 1 nm through the etching process in the one cycle. When an etching amount of 4 nm, for example, is required, therefore, the above-mentioned cycle is repeated four times, which requires a total of eight minutes.

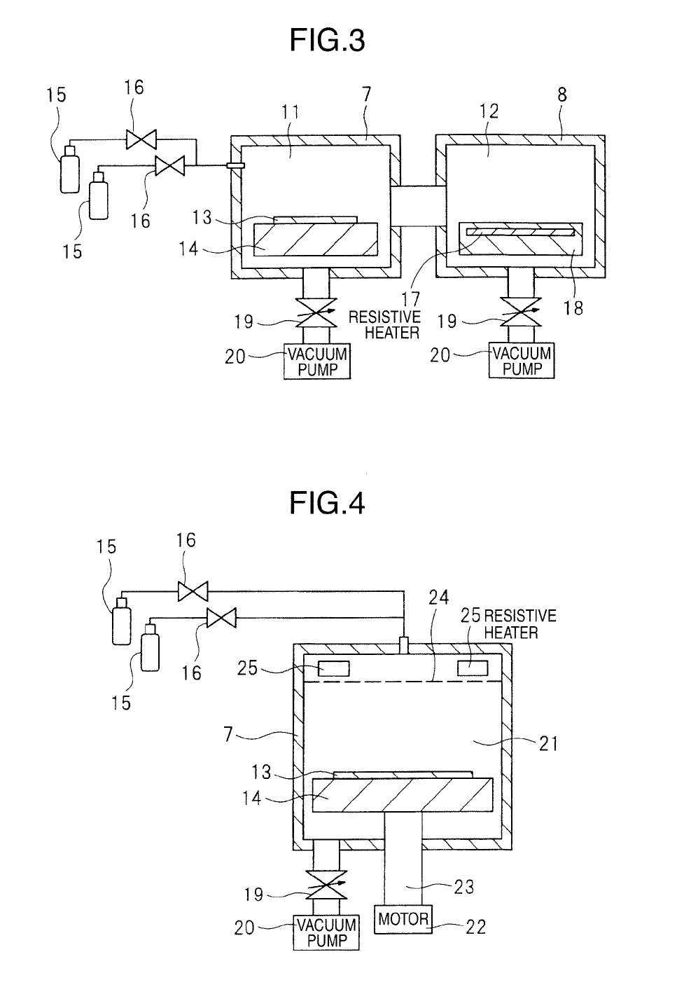

An effect of the present embodiment will be described below with reference to first to third comparative examples respectively illustrated in FIGS. 3 to 5. FIGS. 3, 4, and 5 are respectively schematic views of etching apparatuses in the first, second, and third comparative examples. In the etching apparatus in each of the comparative examples using an adsorption/desorption system, the reason why throughput in manufacturing processes decreases will be described. In each of the comparative examples, the SiO₂ film on the Si wafer is removed using HF gas and NH₃ gas as gas for adsorption.

First, FIG. 3 illustrates the etching apparatus in the comparative example. The etching apparatus uses two processing chambers, i.e., a processing chamber for adsorption 11 composed of a vessel 7 and a processing chamber for heating 12 connected to the processing chamber for adsorption 11 and composed of a vessel 8. The processing chamber for heating 12 performs heat treatment for removing byproducts formed on a wafer 13 using a resistive heater 17. The reason why the two processing chambers are used is that when both adsorption and desorption by heat are performed on one wafer stage within one processing chamber, the temperature of the wafer stage needs to be changed between a room temperature serving as a temperature of the wafer stage required in an adsorption process and 120° C. serving as a temperature of the wafer stage required in a desorption process so that a period of time required to adjust the temperature is lengthened and throughput in wafer processing decreases.

A wafer stage for cooling 14 is arranged within the processing chamber for adsorption 11, and gas cylinders 15 and a vacuum pump 20 are further respectively connected to the wafer stage for cooling 14 via valves 16 and a variable conductance valve 19. A wafer stage for heating 18 for heating the wafer 13 to perform the desorption process is arranged within the processing chamber for heating 12 arranged adjacent to the processing chamber for adsorption 11. The processing chamber for adsorption 11 and the processing chamber for heating 12 are connected to each other. If the processing chamber for adsorption 11 is evacuated, the processing chamber for heating 12 is also evacuated.

A procedure for etching performed when the etching apparatus is used is as follows. First, the wafer 13 is mounted on the wafer stage for cooling 14 whose temperature has been adjusted to 20° C. Then, anhydrous HF gas and NH₃ gas are supplied to the wafer 13 from the gas cylinders 15 via the valves 16, and are adsorbed to an upper surface of the wafer 13. Thus, the adsorbed anhydrous HF and NH₃ gases react with an SiO₂ film to be removed, to generate (NH₄)₂SiF₆.

Then, the wafer 13 is conveyed to the processing chamber for heating 12, and is mounted on the wafer stage for heating 18 housing the resistive heater 17. Then, the wafer stage for heating 18 is heated to 120° C., to desorb (NH₄)₂SiF₆ serving as byproducts from the wafer 13 and exhaust the (NH₄)₂SiF₆ via the variable conductance valve 19 using the vacuum pump 20. In the etching apparatus, such a procedure of adsorption, desorption, and exhaust is repeated as one cycle, to advance etching. When the etching apparatus is used, the two processing chambers are provided to shorten a period of time for heating and cooling. Thus, the etching apparatus increases in size. A processing time is long because the wafer 13 is moved between the two processing chambers, and throughput in etching processing for the wafer 13 is low.

FIG. 4 is a schematic view of the etching apparatus in the second comparative example that performs both adsorption and desorption by heating within one processing chamber 21. That is, the etching apparatus in the second comparative example includes a processing chamber 21 composed of a vessel 7. The processing chamber 21 has a cooling portion and a heating portion in its inner part. In the etching apparatus, heat radiation from a heated shower plate is used in a desorption process. A procedure for etching performed when the etching apparatus is used is as follows.

In an etching process in the second comparative example, a wafer 13 is first mounted on a wafer stage 14 within the processing chamber 21. Then, anhydrous HF gas and NH₃ gas are supplied to the processing chamber 21 from gas cylinders 15 via valves 16, and is adsorbed to an upper surface of the wafer 13. Thus, the anhydrous HF gas and the NH₃ gas, which have been adsorbed to the wafer 13, react with an SiO₂ film to be removed, to generate (NH₄)₂SiF₆.

Then, the wafer stage 14 is raised using a movement shaft 23 connected to a lower surface of the wafer stage 14 and a motor 22, to bring the wafer 13 close to the shower plate 24 provided in an upper part of the processing chamber 21. At this time, a resistive heater 25 heats the shower plate 24. Thus, (NH₄)₂SiF₆ serving as byproducts on the surface of the wafer 13 is desorbed by being heated with radiant heat from the shower plate 24. Then, the desorbed byproducts are exhausted via a variable conductance valve 19 using a vacuum pump 20, and the wafer stage 14 is then lowered to return to its original position, i.e., a position where an adsorption process is performed. Then, the wafer stage for cooling 14 cools the wafer 13 to a temperature of 20° C., to prepare for the subsequent adsorption process. In FIG. 4, the shower plate is indicated by a broken line.

In the etching apparatus, such a procedure of adsorption, desorption, and exhaust is repeated as one cycle, to advance etching. When the etching apparatus is used, a contaminating material is liable to be generated within the processing chamber because there is a mechanical drive portion within the processing chamber 21. Heating and cooling are performed on the same wafer stage 14. Thus, throughput in wafer processing is low because a cycle of heating and cooling takes much time. Further, a period of time is also required to move the wafer up and down, which contributes to a decrease in the throughput.

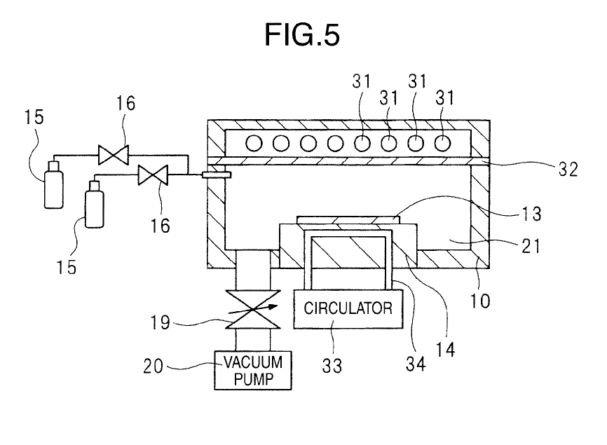

Then, FIG. 5 is a schematic view of the etching apparatus in the third comparative example that performs both adsorption and desorption by heating within one processing chamber 21, and performs heating using halogen lamps 31 in a desorption process. A procedure for etching performed when the etching apparatus is used is as follows.

First, a wafer 13 is mounted on a wafer stage 14 within the processing chamber 21. Then, anhydrous HF gas and NH₃ gas are supplied to the processing chamber 21 from gas cylinders 15 via valves 16, and is adsorbed onto the wafer 13. Consequently, the adsorbed anhydrous HF gas and NH₃ gas react with an SiO₂ film, to generate (NH₄)₂SiF₆ on an upper surface of the wafer 13. Then, the upper surface of the wafer 13 is irradiated with infrared light via a silica glass plate 32 using the halogen lamps 31 provided in an upper part of the processing chamber 21, to heat the wafer 13. As a result, (NH₄)₂SiF₆ serving as byproducts on the surface of the wafer 13 is sublimed and desorbed. Then, the desorbed byproducts are exhausted via a variable conductance valve 19 using a vacuum pump 20. Then, the wafer stage 14 is cooled to 20° C. using a circulator 33 outside the processing chamber 21 and a cooling line 34 within the wafer stage 14, to prepare for the subsequent adsorption process.

In the etching apparatus, such a procedure of adsorption, desorption, and exhaust is repeated as one cycle, to advance etching. When the etching apparatus is used, heating and cooling are performed on the same wafer stage. Thus, throughput in wafer processing is low because a cycle of heating and cooling takes much time.

The etching apparatus that performs etching using the adsorption/desorption system has high selectivity and high controllability. If heating is performed in the desorption process, like in each of the comparative examples, a period of time to cool the temperature of the wafer to 20° C. needs to be set after the etching apparatus performs the desorption process by raising the temperature of the wafer to 100° C. before proceeding to the subsequent adsorption process. Thus, in each of the comparative examples, three minutes are required to perform the processes in one cycle in which etching can be performed by 1 nm, and a total of 12 minutes are required when the one cycle is repeated four times to perform etching by an etching amount of 4 nm. Thus, in the etching apparatus using the adsorption/desorption system by heating, the throughput in the wafer processing is low in any case.

On the other hand, according to the present embodiment, the byproducts on the surface of the wafer can be desorbed by the irradiation of the vacuum-ultraviolet light having a low power density. Accordingly, the temperature of the wafer is prevented from being higher than necessary in the desorption process. Thus, a period of time required to cool the wafer can be more significantly decreased than that in each of the comparative examples. As a result, throughput in an etching process for a semiconductor wafer can be improved by using the etching apparatus according to the present embodiment. That is, in the etching apparatus using the adsorption/desorption system having high selectivity and high controllability, high throughput can be implemented.

In the etching apparatus in the first comparative example (see FIG. 3), the processing chamber for adsorption and the processing chamber for heating are separately provided to shorten a period of time required to heat and cool the wafer stage. Thus, the size of the etching apparatus increases, and the manufacturing cost of a semiconductor device increases. 1.5 On the other hand, the etching apparatus according to the present embodiment need not be separately provided with a processing chamber for heating, and requires only one processing chamber. Thus, the size of the etching apparatus can be decreased. By using the etching apparatus according to the present embodiment, therefore, the manufacturing cost of a semiconductor device can be reduced.

In the etching apparatus in the second comparative example (see FIG. 4), the mechanical drive portion is provided within the processing chamber. Thus, the probability that the contaminating material is generated within the processing chamber is high, and the contaminating material easily adheres to the surface of the wafer. On the other hand, in the etching apparatus according to the present embodiment, a mechanical drive portion for the purpose of raising and lowering the wafer stage, for example, is not provided within the processing chamber. Thus, a contaminating material can be prevented from being generated within the processing chamber. That is, the water stage is fixed within the processing chamber. When the etching apparatus according to the present embodiment is used, therefore, dust or the like within the processing chamber can be easily exhausted, the yield of the semiconductor device can be increased, and the reliability of the semiconductor device can further be enhanced.

While a case where the coiled antenna 46 (see FIG. 1) is used as the radical source has been described in the configuration of the etching apparatus according to the present embodiment, a microwave-excited radical source may be used. While the radical source 44 (see FIG. 1) is used, and the radical including NH₃ gas and NF₃ gas is used as the etchant in the above, a combination of an H₂O vapor and anhydrous HF gas may be used as the etchant without using the radical source 44, for example. In this case, the etching apparatus according to the present embodiment includes a vapor supply unit outside the processing chamber in addition to a gas supply unit.

A second embodiment will be described with reference to FIG. 2. An etching apparatus according to the present embodiment used for a process of etching away a silicon nitride (SiN) film on an Si wafer using a radical supplied from a carbon tetrafluoride (CF₄) plasma and nitric oxide (NO) gas will be described below. FIG. 2 is a schematic view illustrating a configuration of the etching apparatus according to the present embodiment.

As illustrated in FIG. 2, the etching apparatus according to the present embodiment includes a processing chamber 21 within a cylindrical vessel 10. A wafer stage 14 is arranged in a lower part of the processing chamber 21. The vessel 10 has a wafer conveyance port 41, which is used to carry a wafer 13 into the processing chamber 21 and can be opened and closed, on its sidewall. On the processing chamber 21, a plasma generation chamber 52 within a cylindrical vessel 9 provided continuously from the processing chamber 21 with a perforated plate 51 made of silica sandwiched therebetween and a helical antenna 53 provided to wrap around the outer periphery of the vessel 9 are provided. A lamp unit 42 is provided on the plasma generation chamber 52 with a silica glass plate 32 sandwiched therebetween, and a plurality of lamps for near-ultraviolet light irradiation 55 is arranged within a lamp unit 42.

An airtight structure is formed using vacuum seal means such as an O-ring between the processing chamber 21 and the perforated plate 51, between the perforated plate 51 and the plasma generation chamber 52, between the plasma generation chamber 52 and the silica glass plate 32, and between the silica glass plate 32 and the lamp unit 42. The processing chamber 21 and the plasma generation chamber 52 between which gas can move via the perforated plate 51 can be evacuated using a vacuum pump 20 connected to the processing chamber 21 via a variable conductance valve 19. Pressure within the processing chamber 21 can be kept constant by the variable conductance valve 19 and the vacuum pump 20 with a desired flow of process gas caused to flow from gas cylinders 15.

The processing chamber 21 and the plasma generation chamber 52 can be considered as one processing chamber a part of which is partitioned by the perforated plate 51. That is, gas or a vapor can move between the processing chamber 21 and the plasma generation chamber 52, and atmospheric pressure can be kept identical between.

The etching apparatus is provided with a gas supply unit including the plurality of gas cylinders 15 and a plurality of valves 16. Gas supplied from some of the gas cylinders 15 is introduced into the inner periphery of the plasma generation chamber 52 from a donut-shaped gas rectifier 54 via the valves 16. The gas introduced into the plasma generation chamber 52 is activated by a plasma 50 generated within the plasma generation chamber 52 with high frequency power fed to the helical antenna 53, i.e., a coil from a high frequency power source 47, to generate a radical. The radical thus generated is dispersed in the plasma generation chamber 52, and is supplied to the processing chamber 21 after passing through a plurality of holes of the perforated plate 51 made of silica, to reach a surface of the wafer 13.

The others of the plurality of gas cylinders 15 are connected to the plasma generation chamber 52 sequentially via the valves 16 and a gas introduction pipe 45. A part, to which the gas introduction pipe 45 is connected, of the plasma generation chamber 52 is a lower part of a sidewall of the vessel 9 surrounding the plasma generation chamber 52. That is, gas within the gas cylinder 15 is introduced into an area in a lower part of the plasma generation chamber 52 and above the perforated plate 51 made of silica sequentially via the valve 16 and the gas introduction pipe 45.

The wafer stage 14 includes thermoelectric modules 56 The temperature of the wafer 13 mounted on the wafer stage 14 can be cooled to 30° C. or less during an etching process by radiating heat to a heat exchanger (not illustrated). The wafer stage 14 further includes a lift pin (not illustrated) for raising and lowering the wafer.

A material for the vessel 9 surrounding the plasma generation chamber 52 is desirably a material having high plasma resistance, having a small dielectric loss, and hardly causing generation of a contaminating material or contamination. Accordingly, the material for the vessel 9 desirably includes fused silica, a pure alumina sintered body, and a yttria sintered body. A material for the vessel 10 surrounding the processing chamber 21 is desirably a metal having excellent plasma resistance and hardly generating heavy-metal contamination or contamination with a contaminating material in the wafer 13. Accordingly, the material for the vessel 10 desirably includes aluminum whose surface has been alumited. A material for the wafer stage 14 desirably includes aluminum whose surface has been alumited and a titanium alloy.

On the plasma generation chamber 52, the silica glass plate 32 is arranged to close an upper opening of the vessel 9. An airtight state is maintained using vacuum seal means such as an O-ring between the plasma generation chamber 52 and the silica glass plate 32. A material for the silica glass plate 32 is desirably a material having high transmissivity of near-ultraviolet light. Accordingly, the material for the silica glass plate 32 is desirably a raw material having a significantly high purity, and includes ultrapure fused silica glass fused with an oxyhydrogen flame or silica glass obtained by hydrolyzing silicon tetrachloride (SiCl₄) using a Bernoulli's method

While an example using silica glass for a window between the plasma generation chamber 52 and the lamp unit 42 will be described in the present embodiment, a material for the window may include a fluoride material such as calcium fluoride (CaF₂) or magnesium fluoride (MgF₂).

The donut-shaped gas rectifier 54 is provided as a rectification unit in an upper part of the plasma generation chamber 52 and in the vicinity of the silica glass plate 32, and can supply the gas supplied from the gas cylinder 15 to the top of the plasma generation chamber 52. A shape of the rectification unit is selected, as needed, for the purpose of changing a form of supplying the radical to the processing chamber 21. If a disk-shaped shower plate, for example, is used, the radical can be uniformly introduced into the processing chamber 21. In the case, a material for a structure constituting the rectification unit may be desirably a material having high plasma resistance and hardly causing a contaminating material and contamination, i.e., fused silica, a pure alumina sintered body, or a yttria sintered body

The lamp unit 42 including the lamps for near-ultraviolet light irradiation 55 is provided on the silica glass plate 32. The near-ultraviolet light irradiation 55 can include a lamp using a dielectric barrier discharge of rare gas as an excitation source En the present embodiment, a lamp having a center wavelength of 308 nm using a discharge of XeCl as an excitation source is used. The power density of the lamp for near-ultraviolet light irradiation 55 is 10 mW/cm². If such near-ultraviolet light is used, light energy having a magnitude of not less than that of bond energy, which is required to decompose byproducts, can be applied. Thus, a bond of the byproducts is broken so that the byproducts can be efficiently desorbed.

The power density of the lamp for near-ultraviolet light irradiation 55 in the present embodiment is 10 mW/cm². Thus, a rise in temperature of the wafer 13 by light irradiation from the lamp for near-ultraviolet light irradiation 55 can be suppressed to be small by using a lamp having a relatively low power density, and the temperature of the wafer 13 is maintained at 30° C. or less. While an example using the lamp for near-ultraviolet light irradiation 55 having a center wavelength of 308 nm by an XeCl discharge has been illustrated, a lamp for irradiating vacuum-ultraviolet light such as a lamp having a center wavelength of 126 nm by an argon (Ar₂) discharge or a lamp having a center wavelength of 146 nm by a krypton (Kr₂) discharge may be used.

The frequency of the high frequency power source 47 connected to the helical antenna 53 is selected, as needed, between 400 kHz and 40 MHz. In the present embodiment, the frequency of the high frequency power source 47 is 27.12 MHz The high frequency power source 47 has a frequency matching function using a device (not illustrated). That is, the high frequency power source 47 has a function enabling an output frequency to be changed in a range of ±5% to ±10% with respect to a center frequency of 27.12 MHz and enabling feedback control of the frequency so that a ratio Pᵣ/P_{f} of traveling-wave power P_{f} monitored by an output portion of the high frequency power source 47 to reflective wave power Pᵣ decreases.

The type of gas to be supplied to the plasma generation chamber 52 is selected, as needed, depending on a film to be etched. If an SiO₂ film or an SiON film, for example, is removed, a combination of gas containing hydrogen and gas containing fluorine is used. Examples of the gas containing hydrogen include anhydrous HF, H₂, NH₃, CH₄, CH₃F, CH₂F₂, and CH₃F. Examples of the gas containing fluorine include NF₃, CF₄, SF₆, CHF₃, CH₂F₂, CH₃F, and anhydrous HF.

The gas containing hydrogen or the gas containing fluorine can also be diluted, as needed, by adding inert gas such as Ar, He, or N₂ thereto. If an SiN film is removed, a mixed gas containing nitrogen, oxygen, and fluorine is effectively used in addition to the combination of the gas containing hydrogen and the gas containing fluorine, as described above. Examples of the gas containing nitrogen include N₂, NO, N₂O, NO₂, and N₂O₅. Examples of the gas containing oxygen include O₂, CO₂, H₂O, NO, and N₂O.

The etching apparatus according to the present embodiment includes the processing chamber 21, the perforated plate 51, the plasma generation chamber 52, the wafer stage 14, the thermoelectric modules 56, the silica glass plate 32, the lamp unit 42, the lamps for near-ultraviolet light irradiation 55, and the radical source 44, as described above. Further, the etching apparatus according to the present embodiment includes the gas cylinders 15, the valves 16, the variable conductance valve 19, the vacuum pump 20, the gas introduction pipe 45, the helical antenna (coil) 53, the gas rectifier 54, and the high frequency power source 47.

Etching of the SiN film in the present embodiment progresses by repeating a step of supplying a radical containing fluorine and NO gas to a silicon wafer having the SiN film formed therein and adsorbing the radical and the NO gas to the SiN film, to cause a chemical reaction therebetween, a step of irradiating vacuum-ultraviolet light to desorb byproducts produced by the chemical reaction, and a step of exhausting the desorbed byproducts. A specific procedure for an etching process using the etching apparatus according to the present embodiment will be described below.

First, an SiN film is formed on an upper surface of the wafer 13 using a device (not illustrated). Then, a mask composed of a resist film or the like is formed on an upper surface of the wafer 13 via the SiN film. Then, the wafer 13 from which the SiN film is to be removed is carried into the etching apparatus via the wafer conveyance port 41 by a wafer conveyance device (not illustrated), and is mounted on the wafer stage 14. At this time, the temperature of the wafer stage 14 is controlled to 25° C. by the thermoelectric modules 56, and the temperature of the wafer 13 is maintained at 25° C. Then, the processing chamber 21 is evacuated via the variable conductance valve 19 using the vacuum pump 20 while the wafer conveyance port 41 is closed so that the processing chamber 21 is kept airtight.

On the other hand, CF₄ gas is supplied to the plasma generation chamber 52 from the gas cylinder 15 via the valve 16 and the gas rectifier 54 while high frequency power from the high frequency power source 47 is supplied to the helical antenna (coil) 53, and a current flows through the helical antenna (coil) 53 so that the plasma 50 is formed within the plasma generation chamber 52. In FIG. 2, the plasma 50 is generated at a position enclosed by a broken line. At this time, the flow rate of the CF₄ gas is 100 sccm. Processing gas composed of the CF₄ is activated by the plasma 50, to be an etchant including a radical, and flows into the processing chamber 21 after passing through a plurality of holes of the perforated plate 51 made of silica.

NO gas is supplied to a lower part of the plasma generation chamber 52 via the valve 16 and the gas introduction pipe 45 from the other gas cylinder 15. The NO gas, which has been supplied to a lower part of the plasma generation chamber 52, flows into the processing chamber 21 after passing through the plurality of holes of the perforated plate 51 made of silica. The etchant including the radical, which has flowed into the processing chamber 21, and the NO gas are uniformly dispersed to the entire processing chamber 21, and are adsorbed to the entire upper surface of the wafer 13 mounted on the wafer stage 14. The etchant, which has been adsorbed to the wafer 13, reacts with the SiN film on the surface of the wafer 13 so that byproducts serving as a mixture of Si, N, O, C, and F are formed. Due to an effect of providing the perforated plate 51 made of silica between the wafer 13 and an area where the plasma 50 is generated, ions generated within the plasma 50 are hardly incident on the wafer 13. Therefore, non-selective etching caused by incidence of ions does not occur, and SiN can be selectively etched.

After a lapse of a processing time set to adsorb each etchant to the wafer 13 through the above-mentioned process, to form byproducts, the supply of processing gas is stopped by closing the valves 16 while the high frequency power source 47 is stopped. The gas remaining in the processing chamber 21 is exhausted via the variable conductance valve 19 using the vacuum pump 20.

Then, the lamps for near-ultraviolet light irradiation 55 are turned on to irradiate the surface of the wafer 13 with near-infrared light having a center wavelength of 308 nm. The power density of the irradiated light is 10 mW/cm², and an irradiation time is 50 seconds. Photon energy of the near-ultraviolet light having a wavelength of 308 nm is as relatively high as 389.5 kJ/mol. Thus, a bond and a back bond of the byproducts containing Si, N, C, or F are broken, and the byproducts are desorbed from the surface of the wafer in the form of HCN (hydrogen cyanide), NH₃, or SiF₄. As a result, a part or the whole of the SiN film is removed from the surface of the wafer 3.

During the reaction by the irradiation of the near-ultraviolet light, the temperature of the wafer 13 is controlled by the thermoelectric modules 56, and is maintained at 25° C. The power density of the irradiated light is as relatively low as 10 mW/cm², which hardly affects the temperature of the wafer 13. Even if the thermoelectric modules 56 are not used, the temperature of the wafer 13 is maintained at 30° C. or less.

After a lapse of a processing time set to desorb the byproducts on the surface of the wafer 13, the lamps for near-ultraviolet light irradiation 55 are turned off, and the gas remaining in the processing chamber 21 is exhausted using the vacuum pump 20.

As described above, a part of the SiN film is etched away through the adsorption process for the etchant including the radical and the desorption process for the byproducts by the near-ultraviolet light irradiation. An etching amount in one cycle of the adsorption and the desorption is 0.5 nm, for example, and a period of time required for the processes in the one cycle is one minute and 30 seconds. If an etching amount of 3 nm, for example, is required, therefore, the above-mentioned cycle needs to be repeated six times. In this case, a period of time required therefor is a total of nine minutes.

On the other hand, if heating using the halogen lamps is performed in the desorption process, like in the above-mentioned third comparative example (see FIG. 5), the temperature of the wafer needs to be cooled to 20° after the etching apparatus performs the desorption process by raising the temperature of the wafer to 120° C. before proceeding to the subsequent adsorption process. Thus, a period of time required for the processes in one cycle is approximately three minutes, which is longer than that in the present embodiment. Therefore, a period of time required when the cycle is repeated six times to etch the surface of the wafer by an etching amount of 3 nm is a total of 18 minutes in the third comparative example. An amount of grinding of Si serving as an undercoating material of SiN is a measurement limit or less, and selectivity of SiN and Si is 500 or more.

On the other hand, in the present embodiment, the byproducts can be desorbed by the irradiation of the near-ultraviolet light having a low power density Accordingly, the temperature of the wafer is prevented from being higher than necessary in the desorption process. Thus, a period of time required to cool the wafer can be more significantly decreased than that in each of the comparative examples. Accordingly, throughput in an etching process for a semiconductor wafer can be significantly improved by using the etching apparatus according to the present embodiment. That is, in the etching apparatus using the adsorption/desorption system having high selectivity and high controllability, high throughput can be implemented.

While the configuration in which the lamps for near-ultraviolet light irradiation 55 are provided outside the plasma generation chamber 52 has been described in the present embodiment, the lamps for near-ultraviolet light irradiation 55 may be provided inside the plasma generation chamber 52.

Although the invention made by the inventors has been specifically described based on the embodiments, it will be appreciated that the invention is not limited to the embodiments and that various changes thereto may be made without departing from the scope of the invention.

It should be further understood by those skilled in the art that although the foregoing description has been made on embodiments of the invention, the invention is not limited thereto and various changes and modifications may be made without departing from the spirit of the invention and the scope of the appended claims

1. An etching apparatus comprising:
a processing chamber;
a stage that is provided within the processing chamber and on which a member to be processed is mounted;
a radical source for supplying a radical to the processing chamber;
a vacuum pump for depressurizing the processing chamber; and
a lamp for irradiating the member to be processed with near-ultraviolet light or vacuum-ultraviolet light from the top of the processing chamber,
wherein the member to be processed is etched by repeatedly performing
a first step of supplying the radical from the radical source to the processing chamber, and adsorbing the radical to a surface of the member to be processed, to form byproducts on the surface of the member to be processed,
a second step of irradiating the surface of the member to be processed with the near-ultraviolet light or the vacuum-ultraviolet light from the lamp, to desorb the byproducts from the member to be processed after the first step, and
a third step of exhausting the byproducts desorbed in the second step out of the processing chamber using the vacuum pump.

2. An etching apparatus comprising:
a processing chamber;
a stage that is provided within the processing chamber and on which a member to be processed is mounted;
a gas supply unit used to introduce gas for forming a radical into the processing chamber;
a coil installed in an outer periphery of the processing chamber to generate a plasma within the processing chamber;
a vacuum pump for depressurizing the processing chamber; and
a lamp for irradiating the member to be processed with near-ultraviolet light or vacuum-ultraviolet light from an upper part of the processing chamber,
wherein the member to be processed is etched by repeatedly performing
a first step of generating the plasma in a predetermined region within the processing chamber by causing a current to flow through the coil while supplying the gas to the processing chamber from the gas supply unit, and adsorbing the generated radical thereby to a surface of the member to be processed, to form byproducts on the surface of the member to be processed,
a second step of irradiating the surface of the member to be processed with the near-ultraviolet light or the vacuum-ultraviolet light from the lamp, to desorb the byproducts from the member to be processed after the first step, and
a third step of exhausting the byproducts desorbed in the second step out of the processing chamber using the vacuum pump.

3. The etching apparatus according to claim 1, further comprising a vapor supply unit used to supply a vapor to be adsorbed to the member to be processed to the processing chamber,
wherein the radical and the vapor are adsorbed to the surface of the member to be processed, to form the byproducts on the surface of the member to be processed in the first step.

4. The etching apparatus according to claim 2, further comprising a vapor supply unit used to supply a vapor to be adsorbed to the member to be processed to the processing chamber,
wherein the radical and the vapor are adsorbed to the surface of the member to be processed, to form the byproducts on the surface of the member to be processed in the first step.

5. The etching apparatus according to claim 2, further comprising a perforated plate for preventing ions from being incident on the member to be processed between the stage and the region.

6. The etching apparatus according to claim 1, further comprising a cooling device for keeping a temperature of the stage constant.

7. The etching apparatus according to claim 1, wherein
the stage is fixed within the processing chamber.
